(19) United States
(12) Patent Application Publication
(10) Pub. No.: US 2011/0110046 A1
(43) Pub. Date: May 12, 2011

(54) REINFORCEMENT FRAME, COMPONENT UNIT, AND DISPLAY

(75) Inventors: Kohji Itoh, Osaka-shi (JP); Shinji Suminoe, Osaka-shi (JP); Masato Onoue, Osaka-shi (JP); Daisuke Takeda, Osaka-shi (JP)

(73) Assignee: SHARP KABUSHIKI KAISHA, Osaka-shi, Osaka (JP)

(21) Appl. No.: 13/002,806

(22) PCT Filed: May 7, 2009
(86) PCT No.: PCT/JP2009/058610

§ 371 Date: Jan. 6, 2011

(30) Foreign Application Priority Data
Jul. 15, 2008 (JP) 2008-183840

(51) Int. Cl. H05K 7/20

(52) U.S. Cl. 361/709

(57) ABSTRACT

Disclosed is a reinforcement frame (38) fixed to an outer package (37) of a heated component unit in a display (69), wherein a first heat dissipation fin is included in the reinforcement frame (38). With such an arrangement, even when heat generated when a component unit (such as a backlight unit in a liquid crystal display) is driven, e.g. driving heat of various elements included in the component unit, is transmitted to the outer package (37) of the component unit, the driving heat is further transmitted to the reinforcement frame (38) which is in contact with the outer package (37) and dissipated by means of the first heat dissipation fin. Consequently, the various elements in the component unit are not impaired by driving heat.

### TECHNICAL FIELD

The present invention relates to a reinforcement frame that reinforces a component unit such as a backlight unit, a component unit that is provided with the reinforcement frame, and a liquid crystal display apparatus that incorporates such a component unit.

### BACKGROUND ART

These days, cathode-ray-tube display apparatuses have been losing their position as a mainstream product to thin flat-panel display apparatuses (such as liquid crystal display apparatuses and plasma display panel apparatuses). Component units such as a liquid crystal panel and a backlight unit incorporated in a thin flat-panel display apparatus such as a liquid crystal display apparatus also need to be thin.

These component units, however, are deficient in strength if they are made excessively thin. To cope with this problem, for example, a display 169 disclosed in Patent Document 1 adopts, as shown in FIG. 16, a reinforcement rib (a reinforcement frame) 138 which is attached to a chassis 137 on which a display panel 159 is placed.
[Patent Document 1] JP-A-2003-29643

### SUMMARY OF THE INVENTION

### Problems to be Solved by the Invention

Note that the reinforcement rib 138 shown in FIG. 16 includes air holes 191 provided for the purpose of reducing weight and improving heat dissipation performance. However, the reinforcement rib 138 is made by bending a metal sheet to be hat-shaped in section, and the air holes 191 are formed by punching the metal sheet.

This invites an inconvenience that air flowing in through the air holes 191 does not come in contact with sufficiently wide area of the reinforcement rib 138. That is, as a result of excessive pursuit of weight reduction, the total area of the metal sheet forming the reinforcement rib 138 is reduced so much that, even though outside air comes in touch with the metal sheet, heat remaining in the reinforcement rib 138 is not dissipated satisfactorily.

As a result, even though the reinforcement rib 138 is connected to the chassis 137, heat remaining in the chassis 137, for example, heat resulting from the driving of various devices incorporated in the display 169 cannot be easily dissipated through the reinforcement rib 138. In other words, the reinforcement rib 138 cannot be said to be satisfactorily functioning as a heat dissipation member.

The present invention has been made in view of the foregoing. An object of the present invention is to provide a reinforcement frame, etc. functioning as a heat dissipation member as well.

### Means for Solving the Problem

According to one aspect of the present invention, a reinforcement frame attached to an outer package of a component unit that is heated in a display includes a first heat dissipation fin that is provided within the reinforcement frame.

With this structure, even if heat generated when a component unit (such as a backlight unit in a liquid crystal display apparatus) is driven, that is, for example, driving heat of various devices included in the component unit, is transferred to the outer package of the component unit, the driving heat is transferred to the reinforcement frame that is in contact with the outer package, and is further dissipated from the first heat dissipation fin. This prevents the various devices included in the component unit from being deteriorated by the driving heat.

According to the present invention, it is preferable that the first heat dissipation fin extend along a length of the reinforcement frame. With this structure, it is easy to enlarge the area of the first heat dissipation fin that is in contact with ambient air such that the reinforcement frame is cooled easily.

According to the present invention, it is preferable that the reinforcement frame further include a connection port that connects from a space surrounded by an inner wall of the reinforcement frame and the first heat dissipation fin to an outside of the reinforcement frame.

The provision of such a connection port makes it easier for air to flow from outside into the space in the reinforcement frame, and this makes the first heat dissipation fin easy for air to reach. As a result, the reinforcement frame is cooled easily.

In particular, it is preferable that a plurality of connection ports be provided as the connection port, including: a connection port located at one end of the reinforcement frame in a length direction thereof; and a connection port located at another end of the reinforcement frame in the length direction thereof.

With this structure, for example, if the connection port located at one end of the reinforcement frame in the length direction is located on the lower side in the gravity direction, while the connection port located at the other end of the reinforcement frame in the length direction is located on the upper side in the gravity direction, air heated by the driving heat flows in through the connection port that is located on the lower side in the gravity direction, rises up to the connection port on the upper side, and further flows to the outside through the connection port on the upper side. This allows air to come in contact with the first heat dissipation fin easily, and as a result, the reinforcement frame is cooled easily.

According to the present invention, the reinforcement frame may further include a second heat dissipation fin formed on a circumference of the reinforcement frame. With this structure, the second heat dissipation fin, in cooperation with the first heat dissipation fin, further cools the reinforcement frame. In particular, it is preferable that the second fin, as well, extend along a length of the reinforcement frame.

It can be said that the present invention includes a component unit reinforced by any one of the above-described reinforcement frames.

According to the present invention, in a case in which an outer package of a component unit is a cluster of a plurality of outer-package pieces, it is preferable that the reinforcement frame be fitted across and in contact with two or more of the outer-package pieces.

With this structure, the driving heat remaining in each of the outer-package pieces is transferred to the reinforcement frame at once and escapes (in short, the driving heat is transferred from the plurality of outer-package pieces to the reinforcement frame, but the reinforcement frame is cooled). This prevents the various devices included in the component unit from being deteriorated by the driving heat.

It can be said that the present invention includes a display provided with any one of the above-described component units and a housing that covers a fitting surface to which the reinforcement frame is fitted in the component unit.

According to the present invention, in such a display, it is preferable that an air hole facing the connection port of the reinforcement frame be included in the housing.

With this structure, air outside the liquid crystal display apparatus flows into the connection port via the air hole, and the air comes in contact with the first heat dissipation fin. This makes it easier for the reinforcement frame to dissipate heat.

### ADVANTAGES OF THE INVENTION

According to the present invention, driving heat of various devices incorporated in a component unit is dissipated via a reinforcement frame that is provided to reinforce the component unit. That is, the reinforcement frame also functions as a heat dissipation member. Thus, in the component unit to which the reinforcement frame is attached, the various devices are not easily deteriorated by the driving heat.

### BRIEF DESCRIPTION OF DRAWINGS

FIG. 1A A perspective view of an MFF (multifunction frame);

FIG. 1B A sectional view of the MFF of FIG. 1A, taken along line A1-A1′ and viewed from the direction indicated by an arrow in FIG. 1A;

FIG. 1C A sectional view of the MFF of FIG. 1A, taken along line B1-B1′ and viewed from the direction indicated by an arrow in FIG. 1A;

FIG. 2A A perspective view of an MFF that is different from the one shown in FIG. 1A;

FIG. 2B A sectional view of the MFF of FIG. 2A, taken along line A2-A2′ and viewed from the direction indicated by an arrow in FIG. 2A;

FIG. 2C A sectional view of the MFF of FIG. 2A, taken along line B2-B2′ and viewed from the direction indicated by an arrow in FIG. 2A;

FIG. 3A A perspective view of an MFF that is different from those shown in FIGS. 1A and 2A;

FIG. 3B A sectional view of the MFF of FIG. 3A, taken along line A3-A3′ and viewed from the direction indicated by an arrow in FIG. 3A;

FIG. 3C A sectional view of the MFF of FIG. 3A, taken along line B3-B3′ and viewed from the direction indicated by an arrow in FIG. 3A;

FIG. 4A A perspective view of an MFF that is different from those shown in FIGS. 1A, 2A, and 3A;

FIG. 4B A sectional view of the MFF of FIG. 4A, taken along line A4-A4′ and viewed from the direction indicated by an arrow in FIG. 4A;

FIG. 4C A sectional view of the MFF of FIG. 4A, taken along line B4-B4′ and viewed from the direction indicated by an arrow in FIG. 4A;

FIG. 5A A perspective view of an MFF that is different from those shown in FIGS. 1A, 2A, 3A, and 4A;

FIG. 5B A sectional view of the MFF of FIG. 5A, taken along line A5-A5′ and viewed from the direction indicated by an arrow in FIG. 5A;

FIG. 5C A sectional view of the MFF of FIG. 5A, taken along line B5-B5′ and viewed from the direction indicated by an arrow in FIG. 5A;

FIG. 6 An exploded perspective view of a liquid crystal display apparatus;

FIG. 7 A two-view diagram showing a liquid crystal display apparatus, including a plan view as viewed from a rear side and a sectional view taken along line E-E′ and viewed from the direction indicated by an arrow in the plan view;

FIG. 8 An exploded perspective view showing an LED module and a light guide body to be incorporated in a liquid crystal display apparatus;

FIG. 9 A perspective view showing a rear side of a backlight unit to be incorporated in a liquid crystal display apparatus;

FIG. 10 A plan view showing a rear side of a chassis in a backlight unit;

FIG. 11 An exploded perspective view of another example of the liquid crystal display apparatus shown in FIG. 6 (showing merely part of the liquid crystal display apparatus);

FIG. 12 A sectional view of the chassis and the MFF shown in FIG. 11, taken along line F-F′ and viewed from the direction indicated by an arrow in FIG. 11;

FIG. 13 A sectional view showing another example of a chassis and an MFF different from those shown in FIG. 12;

FIG. 14 A plan view showing the rear side of another example of a chassis to be incorporated in a backlight unit that is different from the one shown in FIG. 10;

FIG. 15 A sectional view showing another example of a liquid crystal display apparatus that is different from the one shown in the sectional view of FIG. 7; and

FIG. 16 An exploded perspective view showing a conventional display.

### BEST MODE FOR CARRYING OUT THE INVENTION

Hereinafter, an embodiment of the present invention will be described with reference to the accompanying drawings. Hatching, reference signs for members and the like may sometimes be omitted in a drawing for convenience, and in such a case, a different drawing is to be referred to. A black dot in a drawing indicates a direction perpendicular to the sheet on which the drawing is drawn.

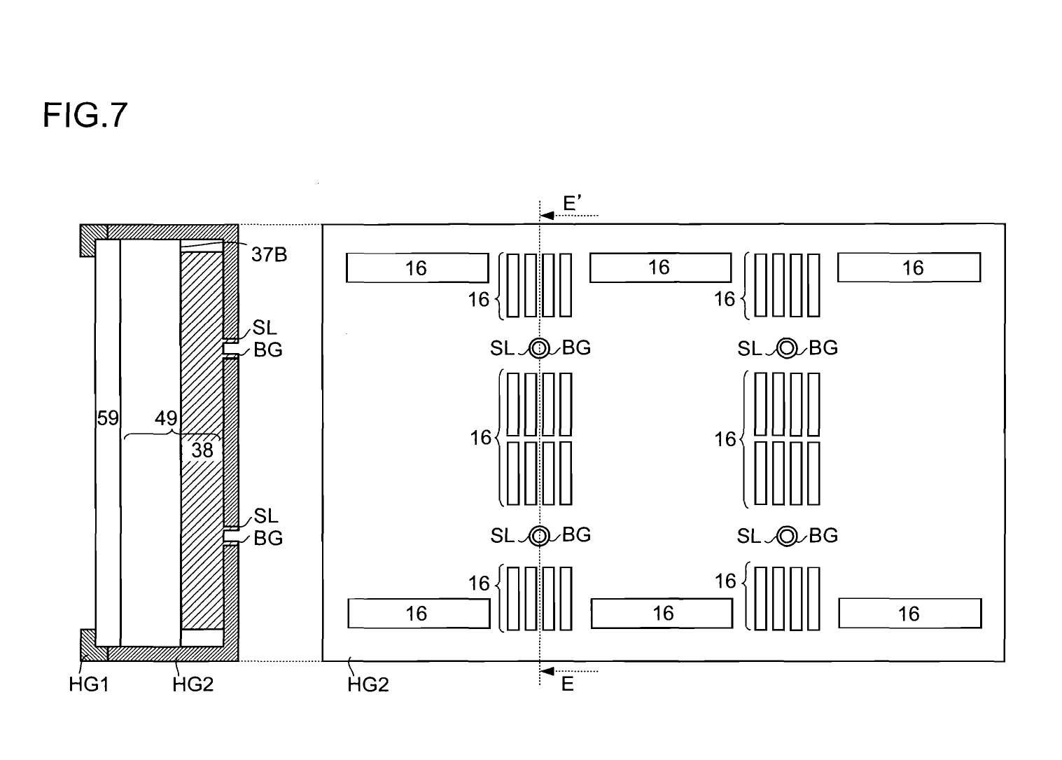

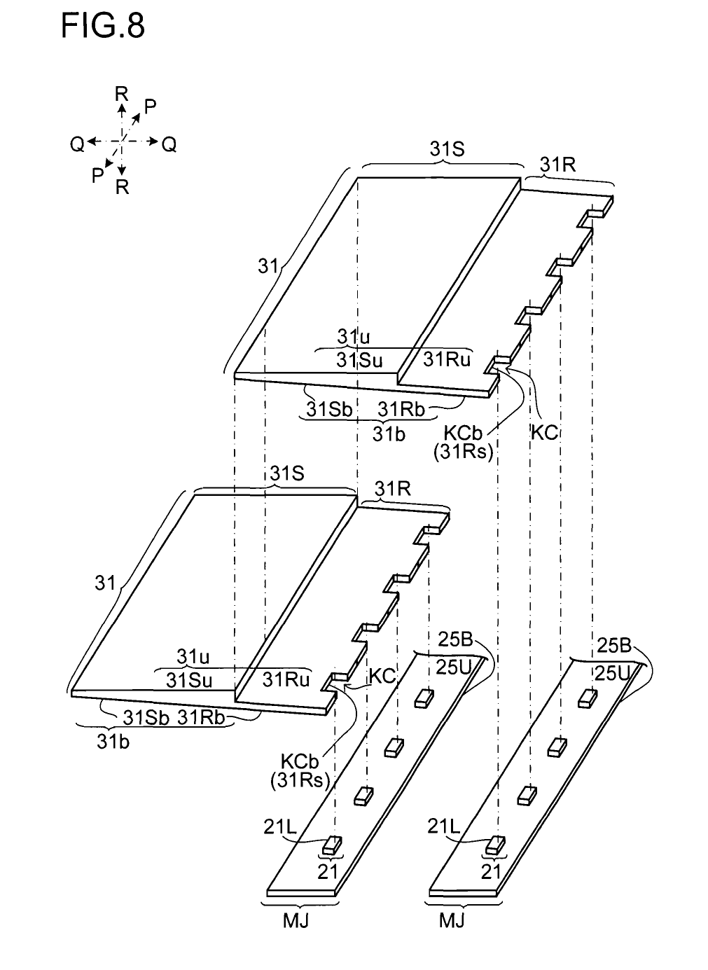

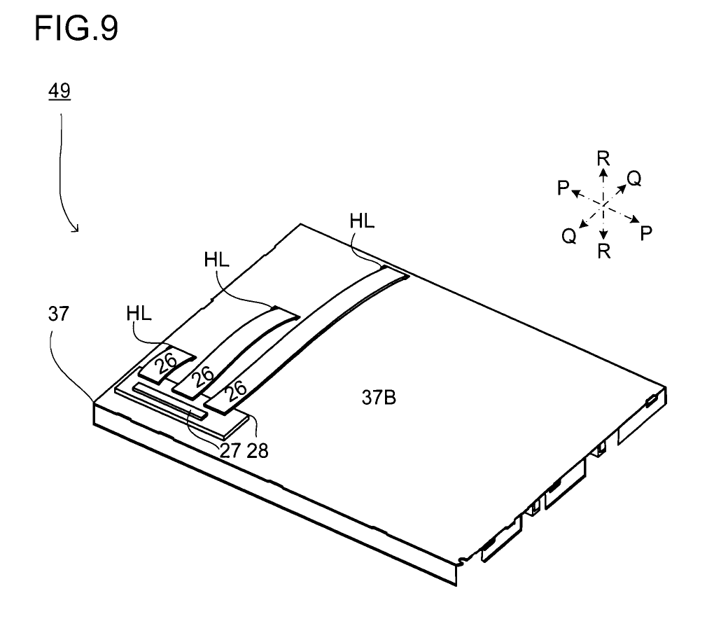

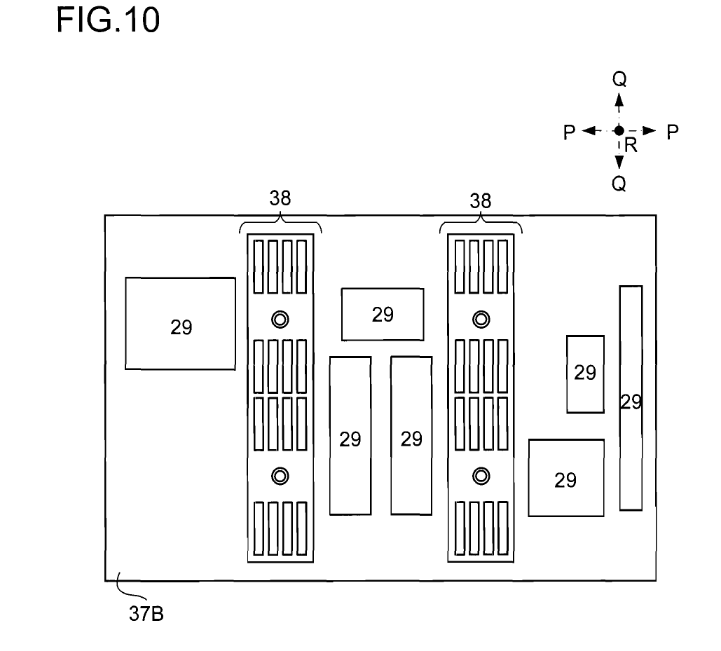

FIG. 6 is an exploded perspective view showing a liquid crystal display apparatus 69. FIG. 7 is a two-view diagram showing the liquid crystal display apparatus 69, including a plan view as viewed from a rear side and a sectional view taken along line E-E′ and viewed from the direction indicated by an arrow in the plan view (incidentally, in the sectional view of FIG. 7, various members are schematically illustrated). FIG. 8 is an exploded perspective view showing LED (light emitting diode) modules MJ and light guide bodies 31 included in the liquid crystal display apparatus 69. FIG. 9 is a perspective view showing a rear side of a backlight unit 49 included in the liquid crystal display apparatus 69.

As shown in FIG. 6, the liquid crystal display apparatus 69 includes: a liquid crystal display panel 59; a backlight unit 49; and a housing HG that holds the liquid crystal display panel 59 and the backlight unit 49 therein (incidentally, hereinafter, a portion of the housing HG that covers the liquid crystal display panel 59 will be referred to as a front housing HG1, and a portion of the housing HG that supports the backlight unit 49 will be referred to as a rear housing HG2).

The liquid crystal display panel 59 is formed by fitting an active matrix substrate 51 including a switching device such as a TFT (thin film transistor) to a counter substrate 52 that faces the active matrix substrate 51 with a seal member (not shown). Then, unillustrated liquid crystal is injected into a clearance between the substrates 51 and 52 (incidentally, polarization films 53 and 53 may be fitted they hold the active matrix substrate 51 and the counter substrate 52 therebetween).

The back light unit 49 shines light onto the liquid crystal display panel 59 which does not emits light by itself. That is, the liquid crystal display panel 59 exerts its display function by receiving light (backlight light) from the backlight unit 49. Thus, the display quality of the liquid crystal display panel 59 will be improved by uniform irradiation of the entire surface of the liquid crystal display panel 59 with the light from the backlight unit 49.

The thus-structured backlight unit 49 includes: an LED module MJ, a mount board 25, a light guide body 31, a diffusion sheet 33, optical sheets 34 and 35, a chassis 37, and a multifunction frame 38 (incidentally, the backlight unit 49, which is formed as a set of various components, is also referred to as a component set).

The LED module MJ includes an LED (light emitting diode) 21 and a mount board 25. The LED 21 is a light emitting device (light source) that emits light. With the LED 21 mounted on an electrode (not illustrated) formed on its surface, the mount board 25 supplies the LED 21 with an electric current from an unillustrated power supply.

Incidentally, as shown in FIG. 8, a surface of the mount board 25 on which the LED 21 is mounted with the electrode interposed therebetween will be referred to as a mount surface 25U, and a rear surface of the mount board 25 opposite to the mount surface 25U will be referred to as a non-mount surface 25B. To ensure sufficient amount of light, it is preferable that a plurality of LEDs (point light sources) 21 be mounted on the mount board 25, and it is still preferable that they be arranged in a row. In the drawings, however, for the sake of convenience, merely part of the LEDs 21 are illustrated (incidentally, hereinafter, the direction in which the LEDs 21 are arranged in a row will be referred to as an arrangement direction P).

As shown in FIGS. 6 and 9, the mount board 25 is, via an FPC (flexible printed circuits) board 26 for connection, connected to an LED driver board 28 on which a control driver (an LED driver 27) for driving the LED 21 is mounted. As a result, a control signal from the LED driver 27 reaches the LED 21 via the LED driver board 28, the FPC board 26, and the mount board 25, and light emission of the LED 21 is controlled by the control signal.

The light guide body 31 performs multiple reflection (mixing) of light it receives from the LED 21 and outputs the resulting light. The light guide body 31 includes, as shown in FIG. 8, a light reception portion 31R that receives light and a light emission portion 31S that is continuous with the light reception portion 31R.

The light reception portion 31R is a plate-shaped member, and includes a cut (main cut) KC formed in part of a side wall thereof that extends along the arrangement direction P. The cut KC has a space sufficient to surround the LED 21 while having its bottom KCb facing a light emitting surface 21L of the LED 21. Thus, when the LED 21 is attached so as to fit in the cut KC, the bottom KCb of the cut KC functions as a light reception surface 31Rs of the light guide body 31. Incidentally, of two surfaces between which side walls of the light reception portion 31R are provided, one that faces the mount board 25 (and thus the chassis 37) will be referred to as a bottom surface 31Rb, and the other that is opposite to the bottom surface 31Rb will be referred to as a top surface 31Ru.

The light emission portion 31S is a plate-shaped member that is arranged continuous with the light reception portion 31R to be located at a position to which light incident on the light reception surface 31Rs proceeds. The light emission portion 31S has a bottom surface 31Sb that forms a surface together (in other words, is flush) with the bottom surface 31Rb of the light reception portion 31R, and on the other hand, has a top surface 31Su that is higher than the top surface 31Ru of the light reception portion 31R so as to form a step.

Furthermore, the top and bottom surfaces 31Su and 31Sb of the light emission portion 31S are not parallel to each other, but one is inclined with respect to the other. Specifically, the top surface 31Su is inclined such that it is closer to the bottom surface 31Sb as the light incident on the light reception surface 31Rs travels farther away from the light reception surface 31Rs. That is, the light emission portion 31S is tapered off such that its thickness (that is, the distance between the top surface 31Su and the bottom surface 31Sb) is gradually smaller as the light incident on the light reception surface 31Rs travels farther away from the light reception surface 31Rs (incidentally, the light guide body 31 including the tapered-off light emission portion 31S is also called a wedge-shaped light guide body 31).

The light guide body 31 including the above-structured light reception portion 31R and the light emission portion 31S receives light through the light emission surface 31Rs and performs mixing of the light between the bottom surface 31b (31Rb, 31Sb) and the top surface 31u (31Ru, 31Su), and emits resulting light through the top surface 31Su (incidentally, the light emitted from the top surface 31Su is referred to as planar light).

The above-structured light guide body 31 and mount board 25 are each provided in a plurality, and the plurality of light guide bodies 31 are arranged in a row in accordance with the LEDs 21 that are arranged in a row (along the arrangement direction P) on the plurality of mount boards 25. Furthermore, by arranging a plurality of rows of the thus arranged light guide bodies 31 in a crossing direction Q that intersects the arrangement direction P (for example, a direction that is perpendicular to the arrangement direction P), the light guide bodies 31 are arranged in a matrix-form.

In particular, where the light guide bodies 31 are arranged in the crossing direction Q, the top surfaces 31Ru of the light receiving portions 31R support the bottom surfaces 31Sb of the light emission portions 31S, and the top surfaces 31Su together form one surface (that is, the top surfaces 31Su are collectively arranged to be flush with each other). Furthermore, where the light guide bodies 31 are arranged in the arrangement direction P, as well, the top surfaces 31Su together form one surface. As a result, the top surfaces 31Su of the light guide bodies 31 form a comparatively large light emission surface by being arranged in the matrix-form (incidentally, the light guide bodies 31 arranged in the matrix-form is also referred to as a tandem light guide body 31).

The diffusion sheet 33 is placed so as to cover the top surfaces 31Su of the light guide bodies 31 as a group, and diffuses planar light coming from the light guide bodies 31 to deliver the light to the entirety of the liquid crystal display panel 59. Moreover, the diffusion sheet 33 reduces noticeability of local degradation of brightness occurring along borders between adjacent ones of the light guide bodies 31 arranged in the matrix-form. Incidentally, the material of the diffusion sheet 33 is not limited to a particular material, and the diffusion sheet 33 may be formed of, for example, a resin or glass.

The optical sheets 34 and 35 are each an optical sheet for polarizing a radiation characteristic of light, having, for example, a prism shape within a sheet surface thereof, and they are placed so as to cover the diffusion sheet 33. As a result, the optical sheets 34 and 35 collect light coming from the diffusion sheet 33 to improve brightness. Incidentally, the optical sheets 34 and 35 are disposed so as to disperse light they collect in directions that cross each other. Incidentally, the diffusion sheet 33 and the optical sheets 34 and 35 will also be collectively referred to as an optical sheet group 36.

The chassis 37 is a housing for housing the LED modules MJ, the light guide bodies 31, the diffusion sheet 33, and the optical sheets 34 and 35 described above. Specifically, the chassis 37 houses them such that the diffusion sheet 33 and the optical sheets 34 and 35 are laid one on top of the other on the top surfaces 31Su of the light guide bodies 31 that are arranged in the matrix-form. Here, the direction in which they are superposed on each other will be referred to as a superposition direction R (the arrangement direction P, the crossing direction Q, and the superposition direction R may be perpendicular to each other).

Incidentally, as shown in FIGS. 6 and 9, in the chassis 37 which functions as an outer package of the backlight unit 59, a pull-out hole HL is formed, and the LED driver board 28, on which the LED driver 27 is mounted, is fitted to a rear surface of the chassis 37. The FPC board 26 connected to the mount board 25 comes to a rear side of the chassis 37 via the pull-out hole HL to be connected to the LED driver board 28.

The multifunction frame (MFF) 38, as shown in FIGS. 6 and 7, is a pillar-shaped member formed of a metal such as iron or aluminum that has comparatively high thermal conductivity, and fitted to a rear surface 37B of the chassis 37 (that is, the rear surface 37B of the chassis 37 is an attachment surface of the MFF 38). As a result, the MFF (a reinforcement frame) 38 reinforces the strength of the chassis 37.

The above-described backlight unit 49 is placed within the box-shaped rear housing HG2, and the frame-shaped front housing HG1 is placed over the rear housing HG2 while pressing the liquid crystal display panel 59 that is superposed on the backlight unit 49. The front housing HG1 is fixed to the rear housing HG2 (incidentally, there is no limitation to the method of the fixing).

In this state, the front housing HG1 and the rear housing HG2 hold the backlight unit 49 and the liquid crystal display panel 59 therebetween, and thereby the liquid crystal display apparatus 69 is completed. Incidentally, the front and rear housings HG1 and HG2 can be an outer package of the liquid crystal display apparatus 69, and thus can also be referred to as a cabinet.

In the above-described liquid crystal display apparatus 69, light from the LEDs 21 in the backlight unit 49 is emitted as planar light from the light guide bodies 31, and the thus emitted planar light passes through the optical sheet group 36 to be emitted as backlight light having enhanced brightness. The thus generated backlight light reaches the liquid crystal display panel 59, which displays an image thereon by using the backlight light.

Note that, as shown in the plan view of FIG. 10, two MFFs 38 are arranged on the rear surface 37B of the chassis 37, and on the other area of the rear surface 37B of the chassis 37 where the MFFs 38 do not exist, various drive circuit boards 29 necessary to drive the liquid crystal display apparatus 69 are placed (incidentally, the LED driver board 28 is an example of the drive circuit boards 29).

The drive circuit boards 29 have various unillustrated devices (heat sources) mounted thereon, and the devices generate heat when they are driven (incidentally, the LED driver 27 is an example of such devices). The heat, that is, driving heat, is transferred to the drive circuit boards 29, and further to the chassis 37 that is in contact with the drive circuit boards 29 (incidentally, the driving heat from the various devices is possibly transferred to the chassis 37 also via the convection of air between the chassis 37 and the rear housing HG2).

In the LED module MJ as well, the LEDs 21 generate heat when they are driven, and the generated heat (driving heat) is transferred to the mount board 25 and further to the chassis 37 via the mount board 25. As a result, a large amount of driving heat remains in the chassis 37 (incidentally, the driving heat of the LEDs 21 is possibly transferred to the chassis 37 also via the convection of air in the backlight unit 49). In short, the backlight unit 59 in the liquid crystal display apparatus 69 is heated by the driving heat from the various devices.

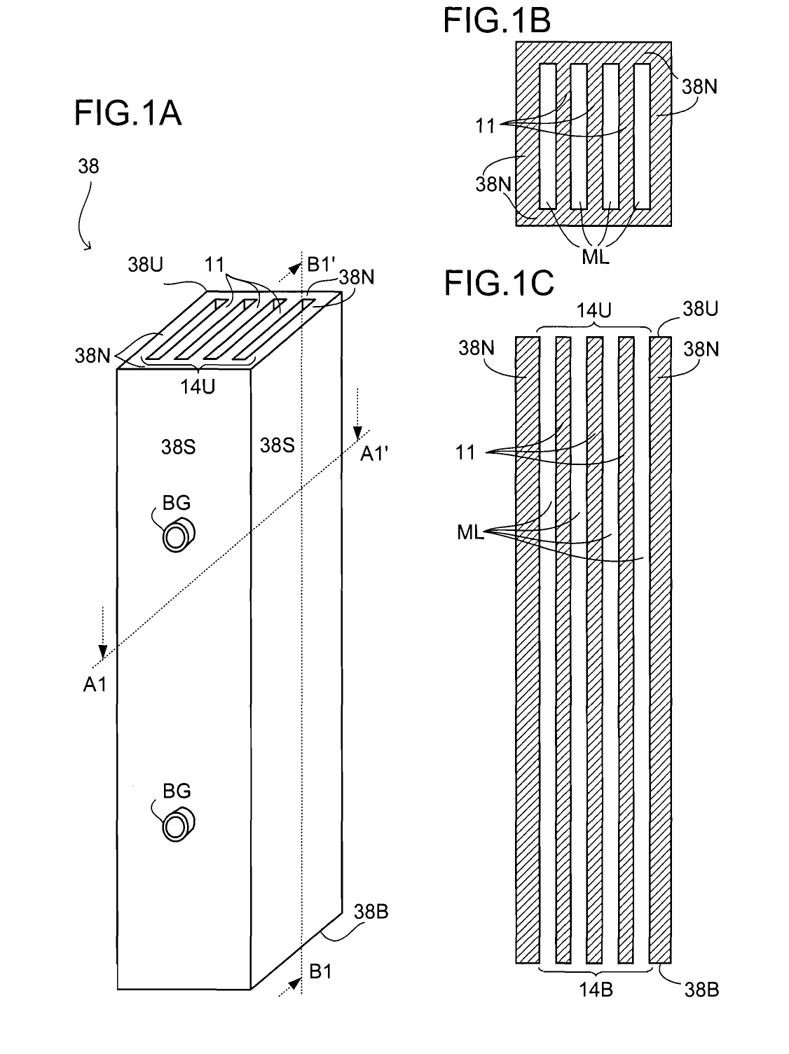

Note that, however, the MFFs 38 are fitted to the rear surface 37B of the chassis 37 in the backlight unit 59 that is heated by the driving heat, and the MFFs 38 are each structured as described below. That is, the MFF 38 includes a first heat dissipation fin 11 placed therein as shown in FIG. 1A which is a perspective view of the MFF 38, FIG. 1B which is a sectional view of the MFF 38 shown in FIG. 1A taken along line A1-A1′ and viewed from the direction indicated by the arrows in FIG. 1A, and FIG. 1C which is a sectional view of the MFF 38 shown in FIG. 1A taken along line B1-B1′ and viewed from the direction indicated by the arrows shown in FIG. 1A.

The first heat dissipation fin 11 is a thin section included in the MFF 38. To be more specific, within the MFF 38, rectangular-parallelepiped main opening holes ML extending in a pillar direction (length direction) of the MFF 38 are formed to be arranged at a predetermined interval, and as a result, a thin section is formed. This thin section is the first heat dissipation fin 11 (incidentally, the main opening holes ML may each be defined also as a space surrounded by the heat dissipation fin 11 and an inner wall 38N of the MFF 38).

With the thus formed first heat dissipation fin 11 included within the MFF 38, even if the driving heat remaining in the chassis 37 is transferred to the MFF 38, the MFF 38 is cooled by ambient air that comes in contact with the first heat dissipation fin 11 (that is, the driving heat transferred to the MFF 38 is dissipated).

Particularly because the first heat dissipation fin 11 forms a heat sink structure having a large area to be in contact with ambient air, the MFF 38 to which driving heat is transferred is cooled efficiently. As a result, driving heat does not stay in the LEDs 21, the various devices such as the LED driver 27, the mount boards 25, or the drive circuit boards 29, and as a result, these devices and boards are prevented from being deteriorated by the driving heat.

Moreover, since the first heat dissipation fin 11 extends along the length of the MFF 38, it is easy to enlarge the area to be in contact with ambient air. Thus, the MFF 38 including the heat dissipation fin 11 functions as a heat dissipation member having comparatively high heat dissipating efficiency. Where the MFF 38, which is a reinforcement member, functions as a heat dissipation member as well, the backlight unit 49 does not need to be provided with another heat dissipation member. As a result, it is possible to reduce the number of components of the backlight unit 49.

The main opening holes ML which are surrounded by the first heat dissipation fin 11 and the inner wall 38N of the MFF 38 are continuous with connection ports 14 (see FIGS. 1A and 1C) through which the main opening holes ML communicate with an outside of the MFF 38. The connection ports 14 (14U, 14B) are located not in a side surface 38S but in a top surface 38U and a bottom surface 38B of the pillar-shaped MFF 38 (that is, there exist a connection port 14U located in the top surface 38U which is one end of the MFF 38 in its length direction and a connection port 14B located in the bottom surface 38B which is the other end of the MFF 38 in its length direction).

With this structure, air heated between the backlight unit 49 and the rear housing HG2 enters the MFF 38 through the connection port 14B formed in the bottom surface 38B located on the lower side in the gravity direction, rises up to the connection port 14U formed in the top surface 38U located on the upper side in the gravity direction, and further flows through the connection port 14U to the outside (such a flow of air taken in through the connection port 14B to be emitted from the connection port 14U is called the chimney effect).

The first heat dissipation fin 11 is cooled while air flows in from the connection port 14B to flow through the main opening holes ML to reach the connection port 14U. That is, the first heat dissipation fin 11 is cooled by a comparatively fast flow of air. As a result, the MFF 38 is cooled more efficiently.

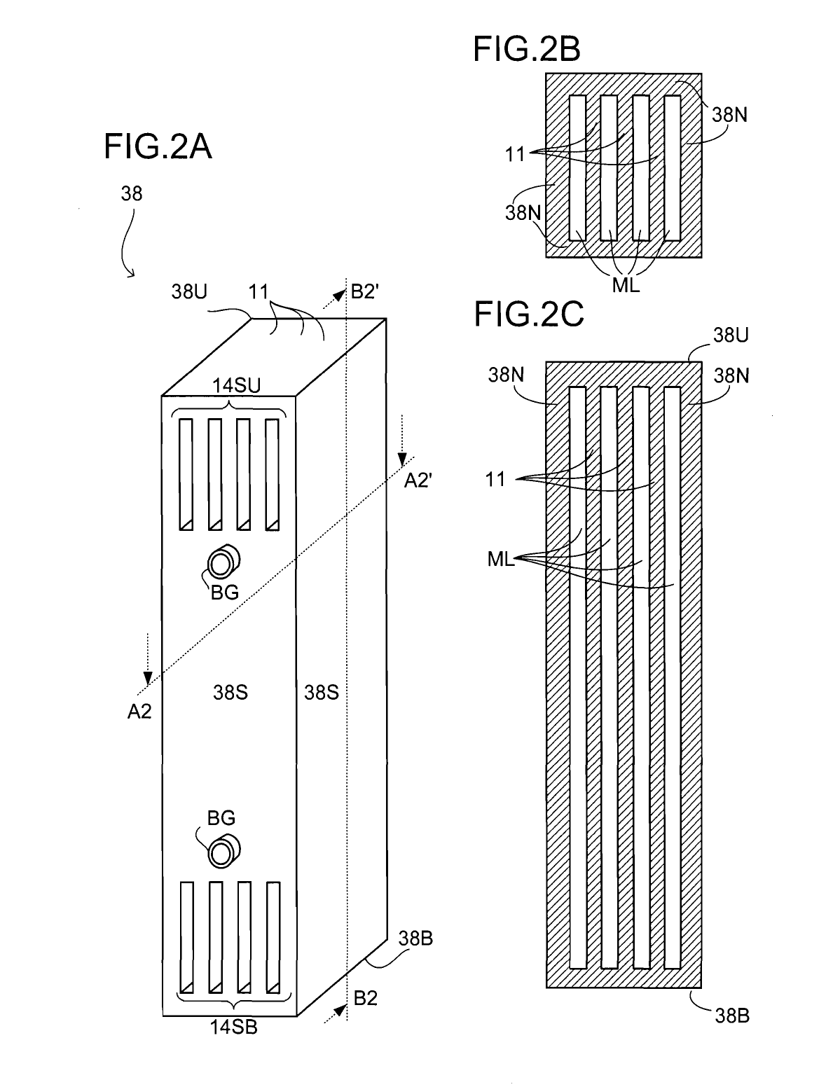

Incidentally, as shown in FIGS. 2A to 2C (drawn in manners similar to those in which FIGS. 1A to 1C are drawn), the connection ports 14 (14SU, 14SB) may also be located in a side surface 38S in addition to the top surface 38U and the bottom surface 18B of the pillar-shaped MFF 38. Here, however, as shown in FIG. 2A, the connection ports 14SU and 14SB are preferably located at one and the other ends of the MFF 38 in the length direction thereof.

With this structure, by air being sucked in through the connection port 14SB and emitted from the connection port 14SU, the air that flows comparatively fast comes in contact with the first heat dissipation fin 11, and thereby the MFF 38 is cooled more efficiently.

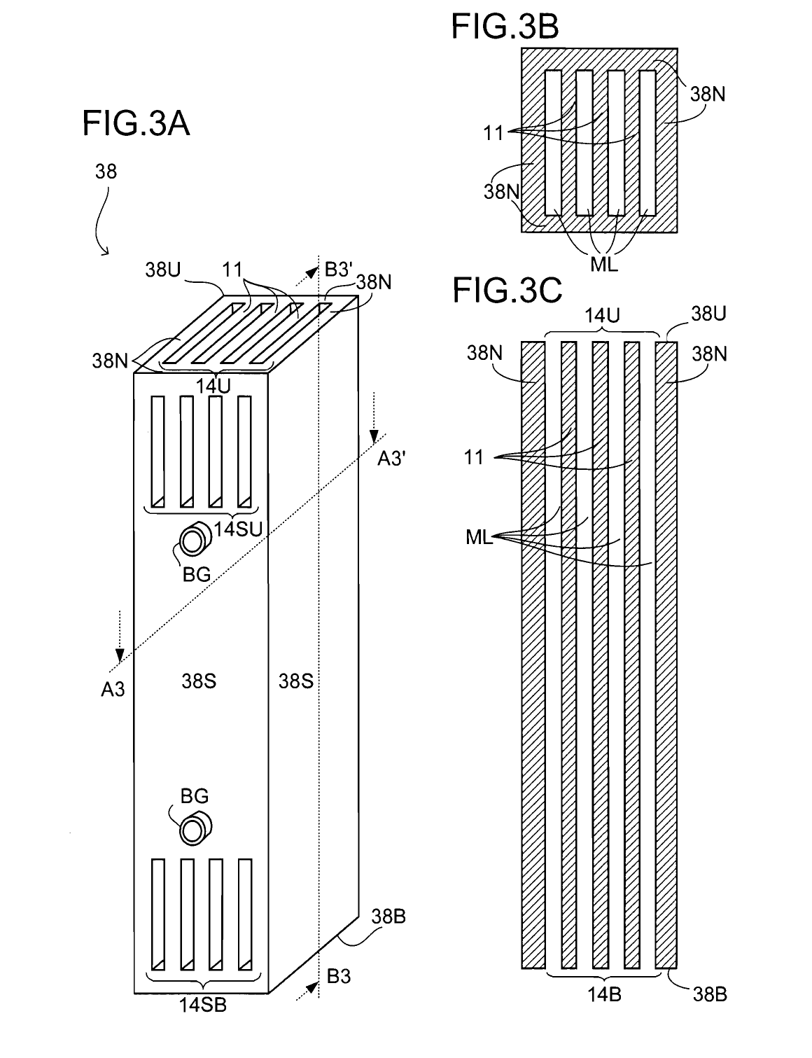

As shown in FIGS. 3A to 3C (drawn in manners similar to those in which FIGS. 1A to 1C are drawn), the connection ports 14 (14U, 14B, 14SU, 14SB) may also be located at both end portions of a side surface 38S in the length direction of the MFF 38, in addition to the top surface 38U and the bottom surface 38B of the MFF 38.

With this structure, by air being sucked in through the connection ports 14B and 14SB and emitted from the connection ports 14S and 14SU, the air flows comparatively fast to come in contact with the first heat dissipation fin 11, and thereby the MFF 38 is cooled more efficiently.

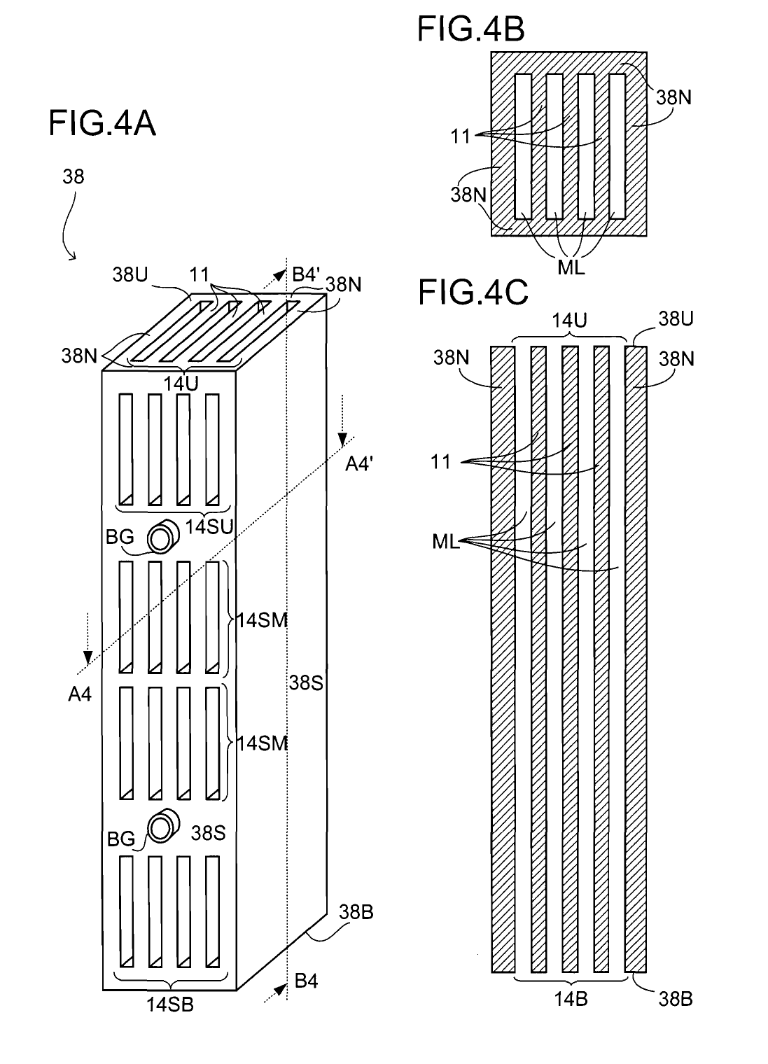

As shown in FIGS. 4A to 4C (drawn in manners similar to those in which FIGS. 1A to 1C are drawn), the connection ports 14 (14U, 14B, 14SU, 14SB, 14SM, 14SM) may also be located at both end portions of a side surface 38S in the length direction of the MFF 38 and at a position between the both end portions, in addition to the top surface 38U and the bottom surface 38B of the MFF 38.

With this structure, by air being sucked in through the connection ports 14B and 14SB and emitted from the connection ports 14S and 14SU, the air flows comparatively fast to come in contact with the first heat dissipation fin 11, and thereby the MFF 38 is cooled more efficiently. And moreover, the air also flows through the connection ports 14SM and 14SM, the MFF 38 is cooled even more efficiently.

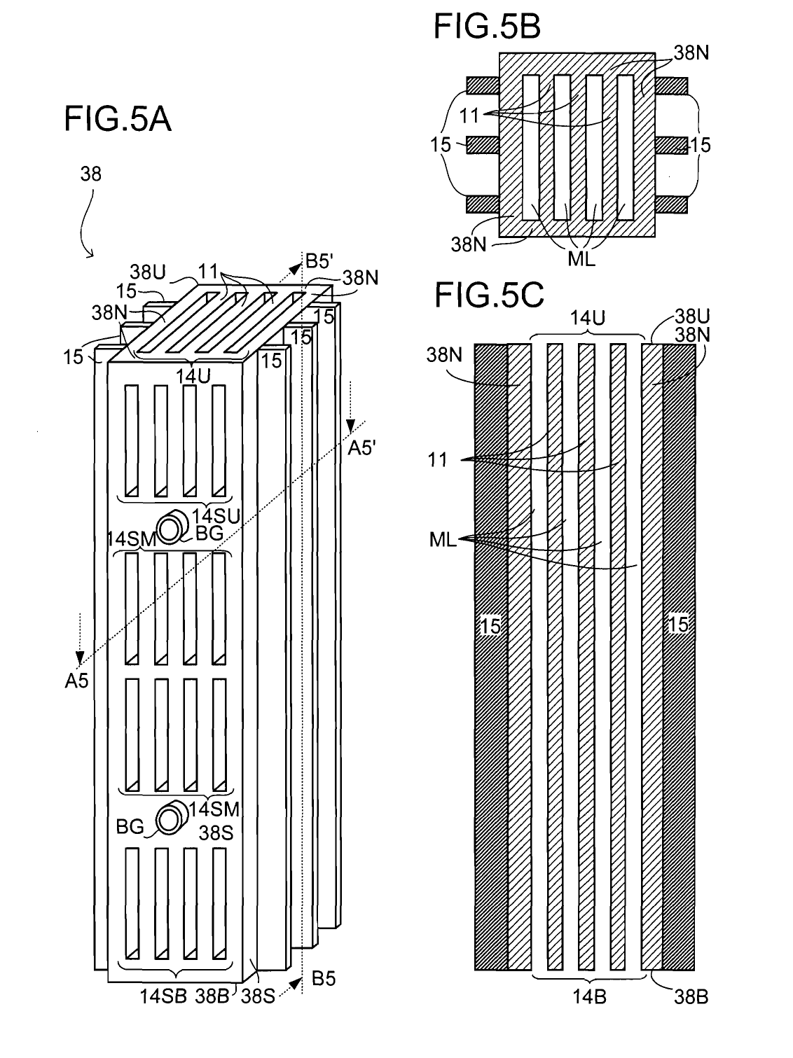

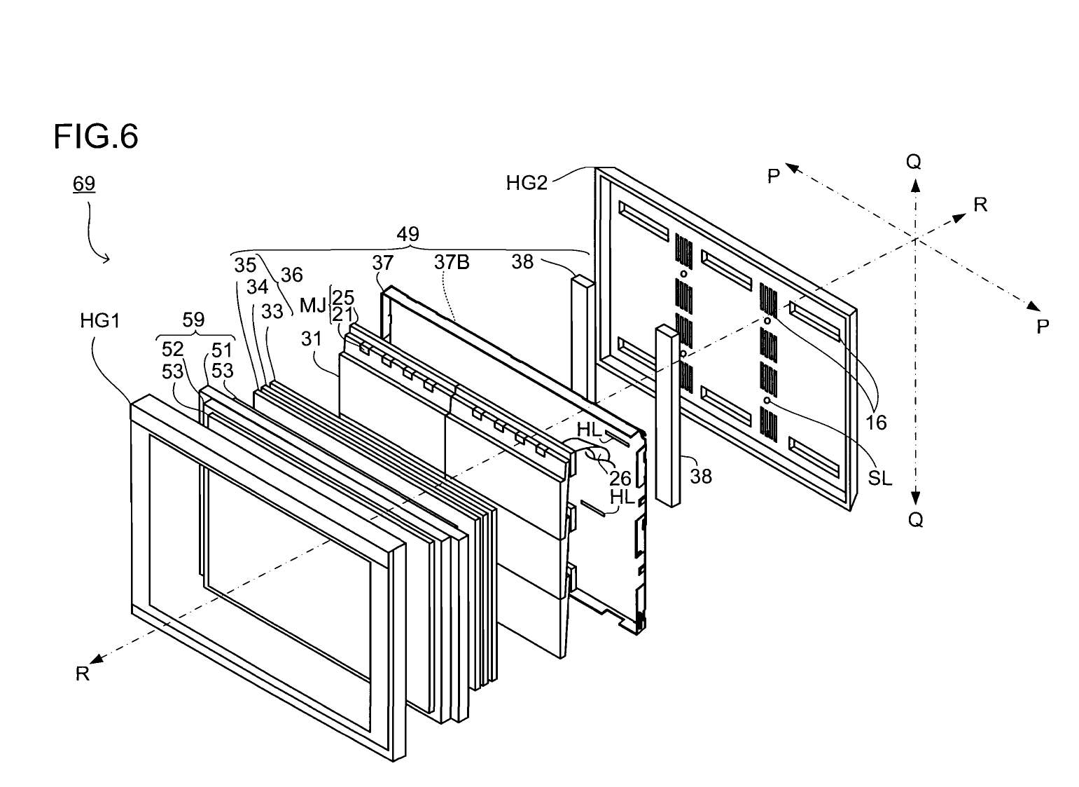

As shown in FIGS. 5A to 5C (drawn in manners similar to those in which FIGS. 1A to 1C are drawn), a second heat dissipation fin 15 may be formed on the circumference of the MFF 38. With this structure, the MFF 38 is cooled by ambient air that comes in contact with the second heat dissipation fin 15. That is, the MFF 38 is cooled by the first and second heat dissipation fins 11 and 15.

If the second heat dissipation fin 15 extends along the length of the MFF 38, it is easy to enlarge the area to be in contact with ambient air. Moreover, air heated by the driving heat remaining in the chassis 37 flows from the end of the second heat dissipation fin 15 located at the side of the bottom surface 38B, which is the bottom in the gravity direction, toward the end of the second heat dissipation fin 15 located at the side of the top surface 38U. As a result, the MFF 38 is cooled by this flow of air (that is, the provision of the second heat dissipation fin 25 makes the MFF 38 function as a heat dissipation member having comparatively heat dissipating efficiency).

As shown in FIG. 7, the chassis MFF 38 fitted to the chassis 37 is covered with the rear housing HG2. In a case in which the connection ports 14 are located on a side surface 38S of the MFF 38 covered with the rear housing HG2, it is preferable that a surface of the rear housing HG2 includes air holes 16 formed to face the connection ports 14 (it is not necessary, however, that all the air holes 16 face the connection ports 14). This is because the MFF 38 is cooled even by air that flows in from the air holes 16 via the connection ports 14.

In the case in which the MFF 38 fitted to the chassis 37 is thus covered by the rear housing HG2, it is preferable that the MFF 38 be in contact with the rear housing HG2. This is because, with this structure, the driving heat transferred to the MFF 38 is further transferred to the rear housing HG2 to be dissipated therefrom.

Incidentally, as shown in FIGS. 1A to 5A, a protruding portion BG that protrudes from a side surface 38S of the MFF 38 that faces the rear housing HG2 is a fitting member for fixing the liquid crystal display apparatus 69 on a wall or the like. The protruding portion BG is, as shown in FIG. 7, fitted into a through hole SL included in a surface of the rear housing HG2, to be exposed outside (incidentally, an opening hole included in the protruding portion BG may be connected to the main opening holes ML).

### Other Embodiments

It should be understood that the embodiments specifically described above are not meant to limit the present invention, and that many variations and modifications can be made within the spirit of the present invention.

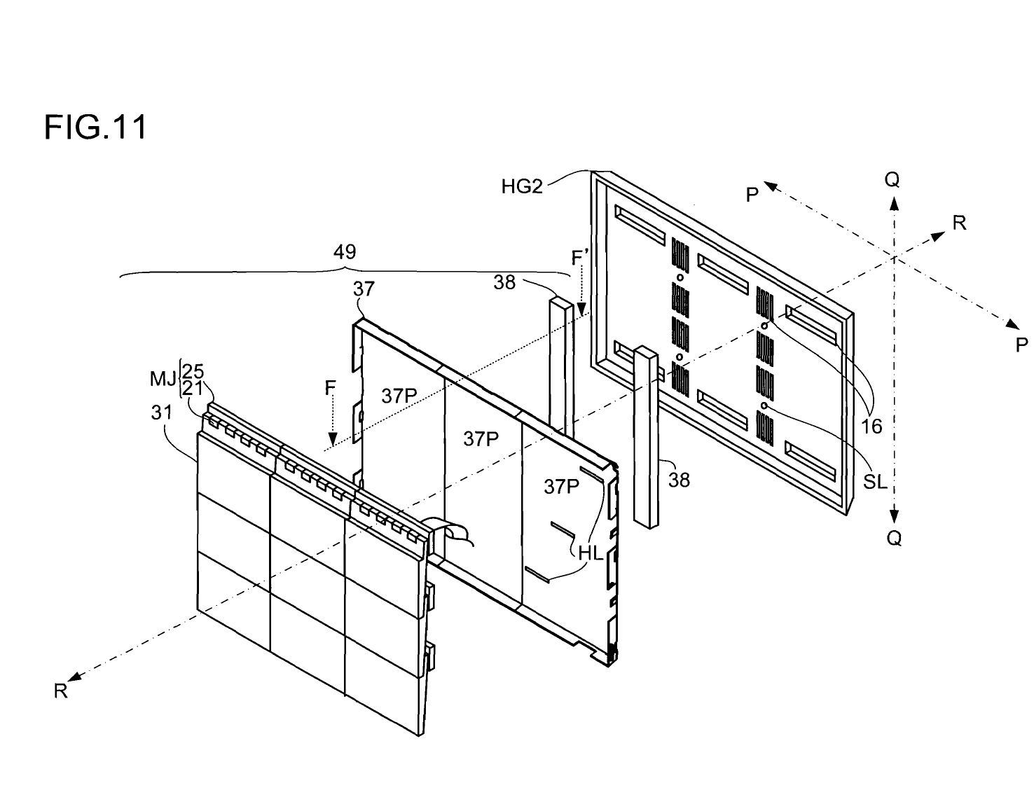

For example, in a large-size backlight unit 49, a chassis 37 as an outer package is sometimes divided into a plurality of pieces for the sake of better workability and lower cost. That is, in some cases, as shown in FIG. 11, a chassis 37 is formed by integrally fitting a plurality of chassis pieces (outer-package pieces) 37P together to form a unit (a cluster).

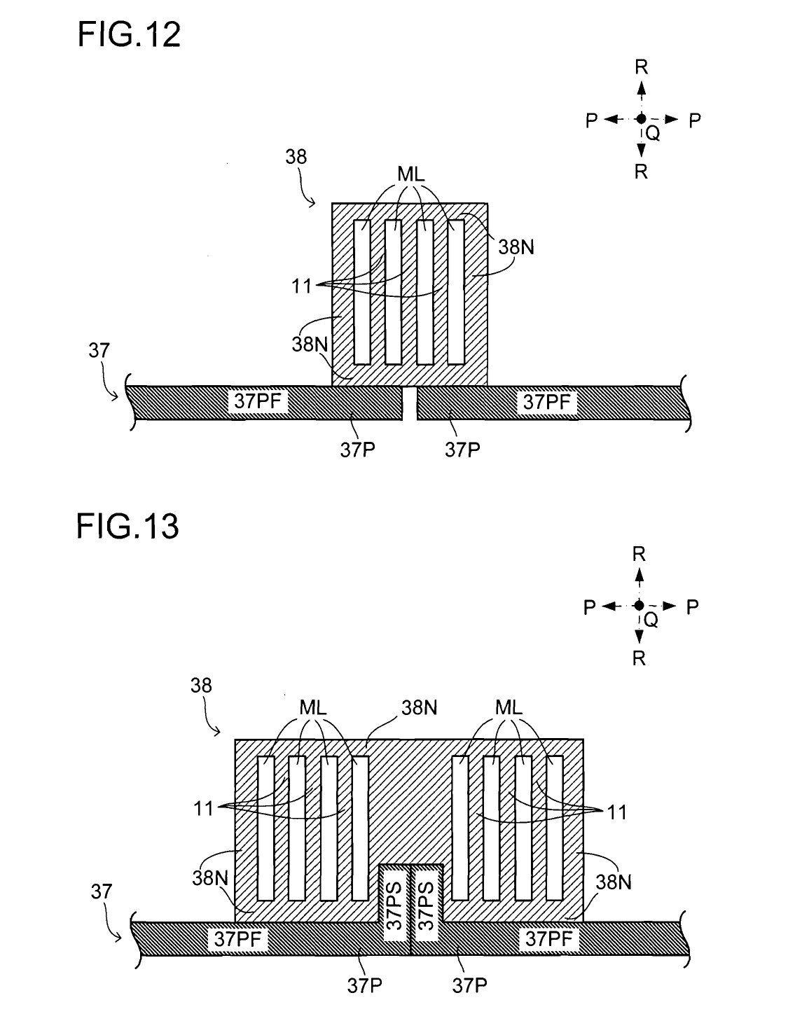

In a backlight unit 49 provided with such a chassis 37, as shown in the sectional view of FIG. 12 (sectional view taken along line F-F′ and viewed from the direction indicated by the arrow in FIG. 11), it is preferable that an MFF 38 be fitted across and in contact with a plurality of chassis pieces 37P arranged flush with each other (in a same plane).

With this structure, the MFF 38, which is used in the regular chassis 37 (undivided chassis 37), functions to connect the chassis pieces 37P. This eliminates the need of providing a member specified for connection, and contributes to reducing the cost of the backlight unit 49.

Furthermore, the thus used MFF 38 allows the driving heat, which remains in each of the independent chassis pieces 37P, to be transferred thereto from both of the chassis pieces 37P across which it is arranged, and dissipates the transferred driving heat. As a result, the various devices and the boards (the mount boards 25 and the drive circuit boards 29) are prevented from being deteriorated by the driving heat.

Incidentally, the method of connecting the MFF 38 with the chassis pieces 37P is not limited to a particular method. For example, they may be connected with each other by using an adhesive or by using a fixing member such as a screw.

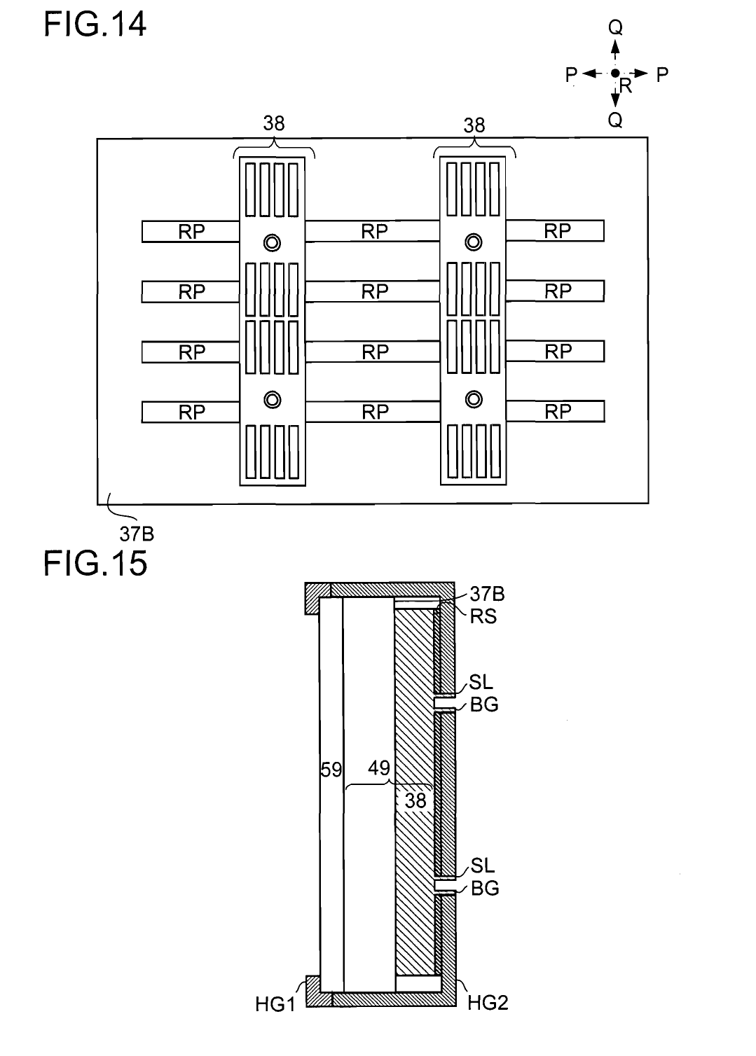

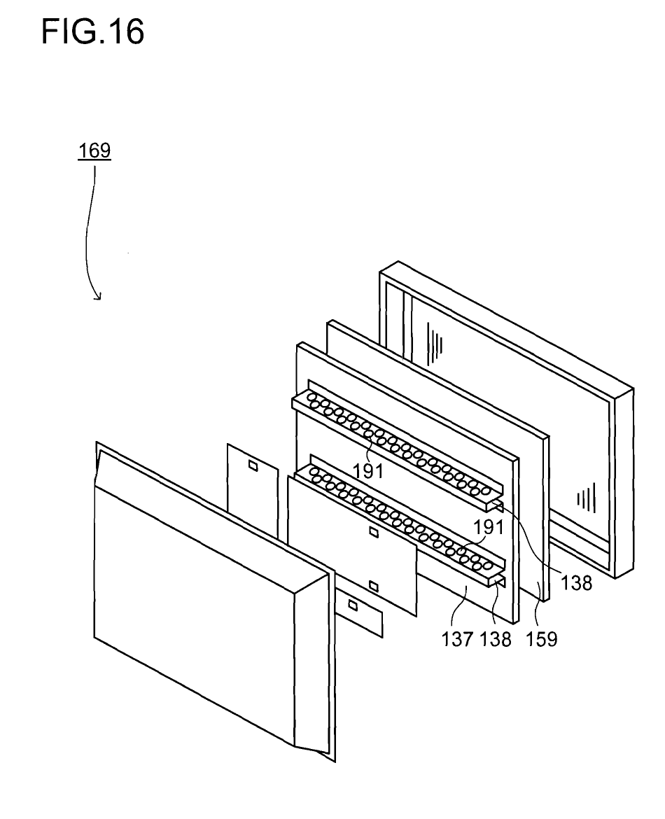

In order to firmly connect the MFF 38 and the chassis components 37P to each other to enhance the strength of the chassis 37, it is preferable to adopt the following structure. That is, as shown in the sectional view of FIG. 13 (which is a diagram showing another example different from the one shown in FIG. 12), the chassis pieces 37P each include, in addition to a main flat portion 37PF, a portion (rise-up portion 37PS) that rises up from the main flat portion 37P. Furthermore, the rise-up portions 37PS of adjacent ones of the chassis pieces 37P are also located adjacent to each other. These adjacent rise-up portions 37PS are together held by the MFF 38.

With this structure, the rise-up portions 37PS are firmly fitted to each other, and thus the strength of the chassis 37 is enhanced compared with the case shown in FIG. 12 in which the MFF 38 is merely fitted across (over) the main flat portions 37PF of adjacent ones of the chassis pieces 37P.

That is, when a chassis 37 is produced with adjacent rise-up portions 37PS, which are formed by applying bending to the chassis pieces 37P, held by an MFF 38, the chassis 37 has enhanced strength compared with a chassis 37 produced with chassis pieces 37P connected with each other by an MFF 38 that is merely placed across main flat portions 37PF of the chassis pieces 37P.

To cope with a case in which so large an amount of driving heat remains in the chassis 37 that it is heated to be excessively hot, the structure shown in the plan view of FIG. 14 may be adopted; that is, a heat dissipating pipe RP is fitted to a chassis 37 which is an outer package of a backlight unit 49, and the heat dissipating pipe RP is connected to an MFF 38. With this structure, the driving heat remaining in the chassis 37 is dissipated via two members, namely, the heat dissipating pipe RP and the MFF 38, and thus the driving heat does not stay in the backlight unit 49.

Alternately, as shown in the sectional view of FIG. 15, a heat dissipating sheet RS may be interposed between a rear housing HG2 and a chassis 37 (specifically, the rear surface 37B of the chassis 37) such that the heat dissipating sheet RS is in contact with the rear housing HG2 and the chassis 37. With this structure as well, the driving heat remaining in the chassis 37 is dissipated via two members, namely, the heat dissipating sheet RS and the MFF 38. As a result, the driving heat does not stay in a backlight unit 49.

The above description has dealt with the liquid crystal display apparatus 69 as an example of a display. This, however, is not meant as a limitation, and the display may be, for example, a plasma display panel apparatus or an organic EL (Electro-Lumines) display apparatus.

The above description has dealt with the backlight unit 49 as a component unit to which the MFF 38 is fitted. This, however, is not meant as a limitation, and for example, the MFF 38 may be fitted to the liquid crystal display panel 59 (that is, the liquid crystal display panel 59 is also a component unit).

### LIST OF REFERENCE SYMBOLS

11 first heat dissipation fin
14 connection port
14U connection port
14B connection port
14SU connection port
14SB connection port
ML main opening hole (space surrounded by the inner wall of the multifunction frame and the first heat dissipation fin)
15 second heat dissipation fin
16 air hole
MJ LED module
21 LED
25 mount board
31 light guide body
37 chassis (outer package of component unit)
37P chassis piece (outer package piece)
37B rear surface of chassis (reinforcement frame fitting surface)
38 multifunction frame (reinforcement frame)
38U top surface of multifunction frame
38B bottom surface of multifunction frame
38S side surface of multifunction frame
38N inner wall of multifunction frame
49 liquid crystal display panel (component unit)
59 backlight unit (component unit)
69 liquid crystal display apparatus

1. A reinforcement frame attached to an outer package of a component unit that is heated in a display, the reinforcement frame comprising: a first heat dissipation fin that is provided within the reinforcement frame.

2. The reinforcement frame of claim 1,
wherein the first heat dissipation fin extends along a length of the reinforcement frame.

3. The reinforcement frame of claim 1, further comprising a connection port that connects from a space surrounded by an inner wall of the reinforcement frame and the first heat dissipation fin to an outside of the reinforcement frame.

4. The reinforcement frame of claim 3,
wherein a plurality of connection ports are provided as the connection port, including:
a connection port located at one end of the reinforcement frame in a length direction thereof; and
a connection port located at another end of the reinforcement frame in the length direction thereof.

5. The reinforcement frame of claim 1, further comprising a second heat dissipation fin formed on a circumference of the reinforcement frame.

6. The reinforcement frame of claim 5, wherein the second heat dissipation fin extends along a length of the reinforcement frame.

7. A component unit reinforced by the reinforcement frame of claim 1.

8. The component unit of claim 7,
wherein
an outer package of the component unit is a cluster of a plurality of outer-package pieces, and
the reinforcement frame is fitted across and in contact with two or more of the outer-package pieces.

9. A display, comprising:
the component unit of claim 7; and
a housing that covers a fitting surface to which the reinforcement frame is fitted in the component unit.

10. A display, comprising:
a component unit that is reinforced by the reinforcement frame of claim 3; and
a housing that covers a fitting surface to which the reinforcement frame is fitted in the component unit,
wherein an air hole that face the connection port is included in the housing.
